(19) United States
(12) Patent Application Publication
(10) Pub. No.: US 2020/0127103 A1
(43) Pub. Date: Apr. 23, 2020

(54) SEMICONDUCTOR DEVICE

(71) Applicant: Samsung Electronics Co., Ltd., Suwon-si (KR)

(72) Inventors: Daewon KIM, Seoul (KR); Bong-soo KIM, Yongin-si (KR); Young Jin CHOI, Hwaseong-si (KR); Byeongjoo KU, lncheon (KR); Man-bok KIM, Yongin-si (KR)

(73) Assignee: Samsung Electronics Co., Ltd., Suwon-si (KR)

(21) Appl. No.: 16/441,540

(22) Filed: Jun. 14, 2019

(30) Foreign Application Priority Data
Oct. 23, 2018 (KR) 10-2018-0126536

(51) Int. Cl. H01L 29/417; H01L 23/522; H01L 29/45

(52) U.S. Cl. CPC H01L 29/41725; H01L 29/45; H01L 23/5226

(57) ABSTRACT

Disclosed is a semiconductor device comprising a semiconductor substrate, a first impurity region and a second impurity region spaced apart from each other in the semiconductor substrate, a bit line on the semiconductor substrate, the bit line extending in a first direction, and a bit line contact connecting the first impurity region to the bit line. The bit line contact includes a metal layer including a first lateral surface and a second lateral surface, and a silicon layer covering the first lateral surface of the metal layer and not covering the second lateral surface of the metal layer.

### CROSS-REFERENCE TO RELATED APPLICATION

This U.S. nonprovisional application claims priority under 35 U.S.C § 119 to Korean Patent Application No. 10-2018-0126536 filed on Oct. 23, 2018 in the Korean Intellectual Property Office, the entire contents of which are hereby incorporated by reference.

### BACKGROUND

Inventive concepts relate to a semiconductor device.

Semiconductor devices are beneficial in electronic industry because of their small size, multi-functionality, and/or low fabrication cost. Semiconductor devices have increasingly integrated with the development of electronic industry. Line widths of patterns of semiconductor devices are being reduced, leading to high integration thereof. However, new exposure techniques and/or expensive exposure techniques are required to be able to develop and form the patterns. Accordingly, it is difficult and/or expensive to highly integrate semiconductor devices. Various researches have thus recently been conducted for new integration techniques.

### SUMMARY

Some example embodiments of inventive concepts provide a semiconductor device with enhanced electrical characteristics and/or a method of fabricating the same.

An object of inventive concepts is not limited to the mentioned above, and other objects which have not been mentioned above will be clearly understood to those of ordinary skill in the art from the following description.

According to some example embodiments of inventive concepts, a semiconductor device may comprise a semiconductor substrate, a first impurity region and a second impurity region spaced apart from each other in the semiconductor substrate, a bit line on the semiconductor substrate, the bit line extending in a first direction, and a bit line contact connecting the first impurity region to the bit line. The bit line contact includes a metal layer including a first lateral surface and a second lateral surface, and a silicon layer covering the first lateral surface of the metal layer and not covering the second lateral surface of the metal layer.

According to some example embodiments of inventive concepts, a semiconductor device may comprise a semiconductor substrate, an interlayer dielectric layer on the semiconductor substrate, a bit line contact penetrating the interlayer dielectric layer and connecting to the semiconductor substrate, and a bit line extending in a first direction on the semiconductor substrate and connects to the bit line contact. The bit line contact includes a silicon layer in contact with the semiconductor substrate, and a metal layer inside the silicon layer. In a second direction, the silicon layer does not cover a lateral surface of the metal layer, the second direction intersecting the first direction.

According to some example embodiments of inventive concepts, a method of fabricating a semiconductor device may comprise forming on a substrate a device isolation layer defining a plurality of active regions, forming in each of the active regions a first impurity region and a second impurity region, forming a contact hole in the first impurity region, coating a silicon layer on bottom and inner surfaces of the contact hole, filling a remaining portion of the contact hole with a metal layer, and forming on the metal layer a bit line running across the substrate in a first direction.

### BRIEF DESCRIPTION OF THE DRAWINGS

FIG. 1 illustrates a plan view showing a semiconductor device according to some example embodiments of inventive concepts.

FIGS. 2A and 2B illustrate cross-sectional views showing a semiconductor device according to some example embodiments of inventive concepts.

FIG. 3 illustrates a perspective view showing a storage node contact.

FIGS. 4A and 4B illustrate cross-sectional views showing a semiconductor device according to some example embodiments of inventive concepts.

FIGS. 5A and 5B illustrate cross-sectional views showing a semiconductor device according to some example embodiments of inventive concepts.

FIGS. 6A, 7A, 8A, 9A, 10A, 11A, and 12A illustrate cross-sectional views showing a method of fabricating a semiconductor device according to some example embodiments of inventive concepts.

FIGS. 6B, 7B, 8B, 9B, 10B, 11B, and 12B illustrate cross-sectional views showing a method of fabricating a semiconductor device according to some example embodiments of inventive concepts.

FIGS. 13A, 14A, and 15A illustrate cross-sectional views showing a method of fabricating a semiconductor device according to some example embodiments of inventive concepts.

FIGS. 13B, 14B, and 15B illustrate cross-sectional views showing a method of fabricating a semiconductor device according to some example embodiments of inventive concepts.

FIGS. 16A and 17A illustrate cross-sectional views showing a method of fabricating a semiconductor device according to some example embodiments of inventive concepts.

FIGS. 16B and 17B illustrate cross-sectional views showing a method of fabricating a semiconductor device according to some example embodiments of inventive concepts.

### DETAILED DESCRIPTION OF EXAMPLE EMBODIMENTS

The following will now describe a semiconductor device according to inventive concepts with reference to accompanying drawings.

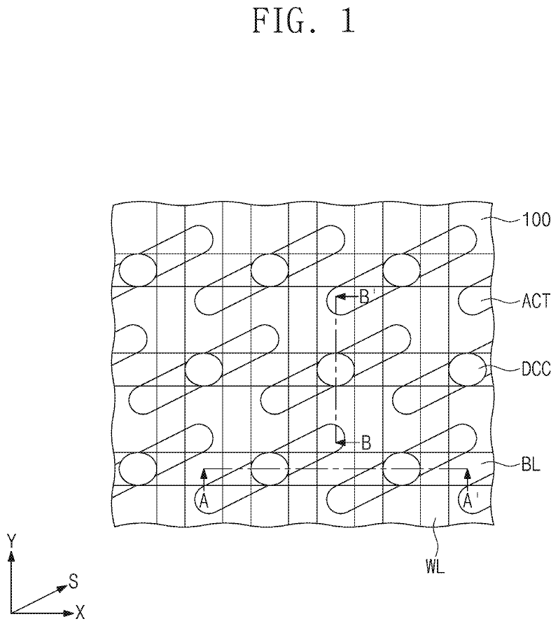

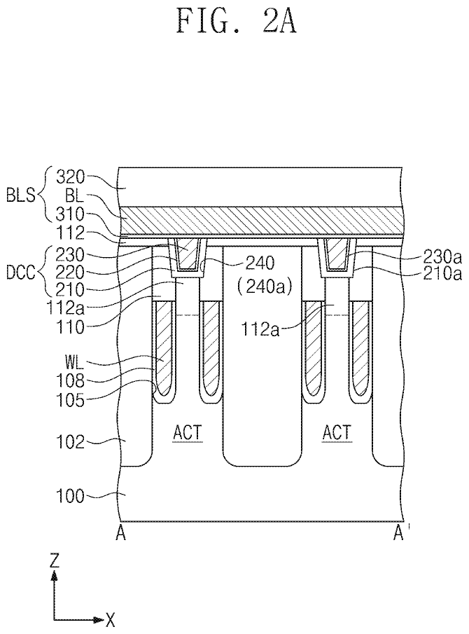

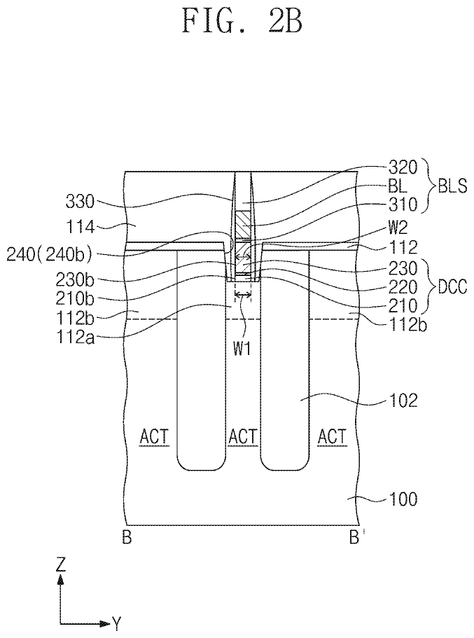

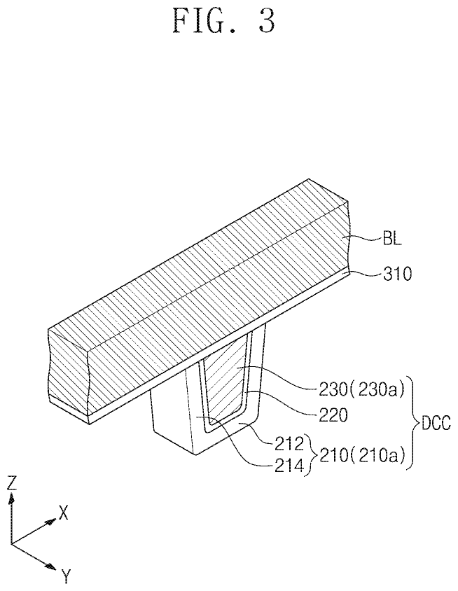

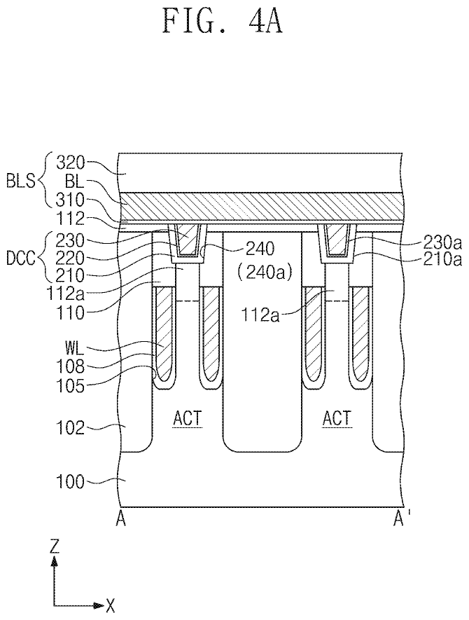

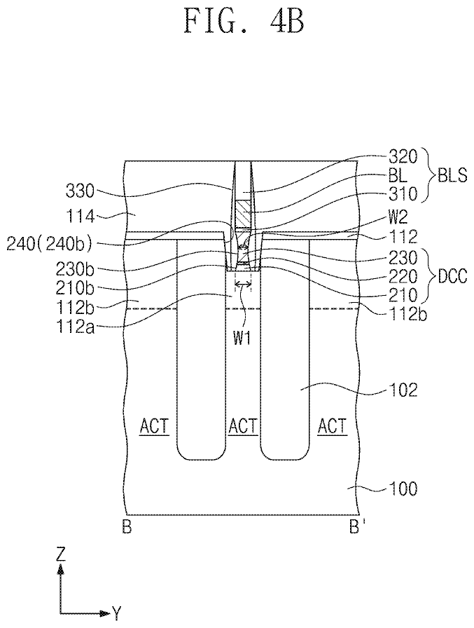

FIG. 1 illustrates a plan view showing a semiconductor device according to some example embodiments of inventive concepts. FIGS. 2A and 2B illustrate cross-sectional views respectively taken along lines A-A′ and B-B′ of FIG. 1, showing a semiconductor device according to some example embodiments of inventive concepts. FIG. 3 illustrates a perspective view showing a storage node contact. FIGS. 4A and 4B illustrate cross-sectional views showing a semiconductor device according to some example embodiments of inventive concepts.

Referring to FIGS. 1, 2A, and 2B, a semiconductor substrate 100 (also referred to hereinafter as a substrate) may be provided. The substrate 100 may be or include a bulk silicon substrate, a silicon-on-insulator (SOI) substrate, a germanium substrate, a germanium-on-insulator (GOI) substrate, a silicon-germanium substrate, a III-V group compound semiconductor substrate, or an epitaxial thin-film substrate obtained by performing selective epitaxial growth (SEG). In figures below, a first direction X and a second direction Y are defined as mutually orthogonal directions parallel to a top surface of the substrate 100. A third direction S is defined as being parallel to the top surface of the substrate 100 and intersecting all of the first and second directions X and Y. A fourth direction Z is defined as being perpendicular to the top surface of the substrate 100.

A device isolation layer 102 may be disposed in the substrate 100. The device isolation layer 102 may include a dielectric material (e.g., silicon oxide). The device isolation layer 102 may define active regions ACT of the substrate 100. When viewed in plan, i.e. from above and parallel to the X-Y plane, the active regions ACT may be portions of the substrate 100 that are surrounded by the device isolation layer 102. Each of the active regions ACT may have an isolated shape. Each of the active regions ACT may have a bar shape elongated in the third direction S. The active regions ACT may be parallel to each other in the third direction S. The active regions ACT may be arranged such that an end of one active region ACT is adjacent to a center of a neighboring active region ACT.

A first impurity region 112a and second impurity regions 112b may be disposed in each of the active regions ACT. The first impurity region 112a may be disposed on a center of each active region ACT, and a pair of the second impurity regions 112b may be disposed on opposite edges of each active region ACT. The first and second impurity regions 112a and 112b may have a different conductive type from that of the substrate 100. The first impurity region 112a may correspond to a common drain region, and the second impurity regions 112b may correspond to source regions. A concentration of impurities in the first impurity region 112a may be the same as a concentration of impurities in the second impurity region 112b; however, inventive concepts are not limited thereto. The first impurity region 112a and the second impurity region 112b may be of the same conductivity type, e.g. may both be N-type.

Word lines WL may run across the active regions ACT. The word lines WL may be disposed in recessions 105 formed in the device isolation layer 102 and the active regions ACT. The recessions 105 may also be called word line trenches. Two word lines WL may extend in the second direction Y and may run across one active region ACT. The word lines WL may have their top surfaces at a lower level than that of the top surface of the substrate 100. Although not shown, the recessions 105 may have their bottom surfaces, which are relatively deeper in the device isolation layer 102 and relatively shallower in the active regions ACT. The word lines WL may be formed of a conductive material, such as doped polysilicon, metal, and/or metal silicide.

A transistor may be constituted by each word line WL and the adjacent first and second impurity regions 112a and 112b. Because the word lines WL are disposed in the recessions 105, the word lines WL may be provided thereunder with channel regions, each of which having lengths greater than a corresponding length of a planar transistor.

A word line dielectric layer 108 may be disposed between the substrate 100 and sidewalls of each of the word lines WL and between the substrate 100 and a bottom surface of each of the word lines WL. The word line dielectric layer 108 may include, for example, a silicon oxide layer, a thermal oxide layer, and/or a high-k dielectric layer. The word line dielectric layer 108 may be formed by in-situ steam generation (ISSG); however, inventive concepts are not limited thereto.

Capping patterns 110 may be disposed on corresponding word lines WL. The capping patterns 110 may be correspondingly disposed on the top surfaces of the word lines WL and top surfaces of the word line dielectric layers 108. The capping patterns 110 may have their linear shapes extending along longitudinal directions of the word lines WL and may entirely cover the top surfaces of the word lines WL. The recessions 105 may have their inner spaces not occupied by the word lines WL, and the capping patterns 110 may fill the unoccupied inner spaces of the recessions 105. The capping patterns 110 may have their top surfaces at the same level as that of the top surface of the substrate 100. The capping patterns 110 may include a dielectric material (e.g., a silicon oxide layer). The capping patterns 110 may include a nitride layer (e.g. a silicon nitride layer).

A first interlayer dielectric layer 112 may be disposed on the top surface of the substrate 100. The first interlayer dielectric layer 112 may cover the top surfaces of the capping patterns 110. The first interlayer dielectric layer 112 may include a single or plurality of dielectric layers. For example, the first interlayer dielectric layer 112 may include a silicon oxide layer such as tetra ethyl ortho silicate (TEOS), a silicon nitride layer, a silicon oxynitride layer, or a plurality of dielectric layers including at least two thereof. The first interlayer dielectric layer 112 may be formed to have island shapes spaced apart from each in a plan view. The first interlayer dielectric layer 112 may be formed to simultaneously cover ends of two neighboring active regions ACT.

A bit line contact DCC may be disposed on a center of each active region ACT between two word lines WL. The bit line contact DCC may penetrate the first interlayer dielectric layer 112 and may have electrical connection with one first impurity region 112a disposed in each active region ACT between two word lines WL. The bit line contact DCC may have a sidewall in contact with a lateral surface of the first interlayer dielectric layer 112. The bit line contact DCC may have a bottom surface at a level between those of the top surface of the substrate 100 and of the top surfaces of the word lines WL. The following will describe in detail the configuration of the bit line contact DCC.

Referring together to FIGS. 1, 2A, 2B, and 3, the substrate 100 may be provided therein with contact holes 240 that penetrate the first interlayer dielectric layer 112 and are formed in portions of the substrate 100 and the device isolation layer 102. The contact holes 240 may extend into the substrate 100 from a top surface of the first interlayer dielectric layer 112. Each of the contact holes 240 may expose the first impurity region 112a between a pair of the word lines WL that overlap one active region ACT. When viewed in plan, i.e. above the top surface of the substrate 100 and parallel to the X-Y plane, the contact hole 240 may extend into the capping pattern 110 adjacent thereto. For example, each of the contact holes 240 may have a first inner wall 240a through which the capping pattern 110 is exposed in the first direction X and a second inner wall 240b through which the device isolation layer 102 is exposed in the second direction Y.

The bit line contacts DCC may be disposed in corresponding contact holes 240 that penetrate the first interlayer dielectric layer 112 and are formed in portions of the substrate 100 and the device isolation layer 102. The bit line contact DCC may be locally formed in a portion of the contact hole 240. For example, the bit line contact DCC may be in contact in the first direction X with the first inner wall 240a of the contact hole 240 and may be spaced apart in the second direction Y from the second inner wall 240b of the contact hole 240. The bit line contact DCC may have a larger width in the first direction X and a smaller width in the second direction Y. However, inventive concepts are not limited thereto. For example, the bit line contact DCC may have the same width in the first and second directions X and Y, or may have a smaller width in the first direction X and a larger width in the second direction Y. The bit line contact DCC may include a silicon layer 210, a first barrier layer 220, and a metal layer 230.

The silicon layer 210 may be provided in the contact hole 240. The silicon layer 210 may be in contact with a bottom surface and the first inner wall 240a of the contact hole 240 and may be spaced apart from the second inner wall 240b of the contact hole 240. The silicon layer 210 may have a first lateral surface 210a in the first direction X in contact with the first inner wall 240a of the contact hole 240 and also have a second lateral surface 210b in the second direction Y not in contact with the second inner wall 240b of the contact hole 240. The silicon layer 210 may have a U-shaped or V-shaped cross-section taken along the second direction Y. The silicon layer 210 may include a bottom segment 212 and sidewall segments 214. The bottom segment 212 may contact the bottom surface of the contact hole 240 and may extend in the first direction X. The sidewall segments 214 may contact the first inner wall 240a of the contact hole 240 and may extend in the fourth direction Z from opposite ends of the bottom segment 212. The bottom segment 212 may be angularly connected to the sidewall segments 214 as shown in FIG. 2A, or may be roundly connected to the sidewall segments 214 as shown in FIG. 3. The silicon layer 210 may contact the first impurity region 112a formed of silicon and may improve interface characteristics between the first impurity region 112a and the bit line contact DCC. The silicon layer 210 may include polysilicon. For example, the silicon layer 210 may include doped or undoped polysilicon.

The metal layer 230 may be disposed on the silicon layer 210. The metal layer 230 may be provided on a top surface of the silicon layer 210 and in an inside of the silicon layer 210. For example, the metal layer 230 may be provided on the bottom segment 212 of the silicon layer 210 and between the sidewall segments 214 of the silicon layer 210. For the bit line contact DCC, the silicon layer 210 may contact a third lateral surface 230a in the first direction X of the metal layer 230 and may expose a fourth lateral surface 230b in the second direction Y of the metal layer 230. The fourth lateral surface 230b of the metal layer 230 may not contact the second inner wall 240b of the contact hole 240. The fourth lateral surface 230b of the metal layer 230 may be coplanar with the second lateral surface 210b of the silicon layer 210. The metal layer 230 may have a top surface at the same level as that of top surfaces of the sidewall segments 214 of the silicon layer 210. The metal layer 230 may improve conductivity of the bit line contact DCC. In addition, the metal layer 230 may be in ohmic contact with the silicon layer 210. The silicon layer 210 may be formed to cover bottom and lateral surfaces of the metal layer 230, and thus an interface may be increased between the silicon layer 210 and the metal layer 230. As a result, a reduced resistance may be achieved at the increased interface between the silicon layer 210 and the metal layer 230. The metal layer 230 may include a metallic material, such as tungsten (W) or titanium (Ti), and/or or a conductive material, such as titanium nitride (TiN) or titanium silicon nitride (TiSiN). The metal layer 230 may be deposited with a deposition process, such as a plasma enhanced chemical vapor deposition (PECVD) process and/or a physical vapor deposition (PVD) process such as sputtering; however, inventive concepts are not limited thereto.

The first barrier layer 220 may be provided between the silicon layer 210 and the metal layer 230. The first barrier layer 220 may improve interfacial characteristics, such as interfacial conductance, between the silicon layer 210 and the metal layer 230. The first barrier layer 220 may include a conductive material, such as titanium nitride (TiN), titanium silicon nitride (TiSiN), or cobalt silicide (CoSix). Optionally, no first barrier layer 220 may be provided.

In some example embodiments, the bit line contact DCC may have a concave lateral surface in the second direction Y. As shown in FIGS. 4A and 4B, the bit line contact DCC may have a lateral surface in the second direction Y. The lateral surface may have a shape that is recessed toward an inside of the bit line contact DCC, for example a shape that is bowed. For example, the metal layer 230 may have a width W2 in the second direction Y, which width W2 may decrease as approaching a central portion of the metal layer 230 from a contact surface between the metal layer 230 and the silicon layer 210. The silicon layer 210 may have a width W1 in the second direction Y, which width W1 may decrease as approaching the contact surface between the silicon layer 210 and the metal layer 230 from a contact surface between the silicon layer 210 and the contact hole 240. An average width W2 in the second direction Y of the metal layer 230 may be less than an average width W1 in the second direction Y of the silicon layer 210. According to inventive concepts, the bit line contact DCC may include the metal layer 230 at its central portion whose width in the second direction Y is smaller than any other portion of the bit line contact DCC, but may have a high conductivity despite its smaller width in the second direction Y. However, inventive concepts are not limited thereto. For example, the width W1 in the second direction Y of the silicon layer 210 may decrease as approaching the contact surface between the silicon layer 210 and the metal layer 230 from the contact surface between the silicon layer 210 and the contact hole 240, but the width W2 in the second direction Y of the metal layer 230 may be constant. For example, the width W2 in the second direction Y of the metal layer 230 may be the same as or greater than the width W1 in the second direction Y of the silicon layer 210, which width W1 at the contact surface between the silicon layer 210 and the contact hole 240. Example embodiments are not limited thereto. For example, the width in the second direction Y of the bit line contact DCC may increase approaching the upper portion from the lower portion thereof.

The following will discuss an example based on FIGS. 2A and 2B.

Referring again to FIGS. 1, 2A, and 2B, bit line structures BLS may be disposed on the first interlayer dielectric layer 112. The bit line structures BLS may extend in the first direction X and may be spaced apart from each other in the second direction Y. Each of the bit line structures BLS may cross over a plurality of the bit line contacts DCC arranged in the first direction X. A single bit line structure BLS may be electrically connected to a plurality of the bit line contacts DCC arranged in the first direction X. The bit line structures BLS may be electrically coupled through the bit line contacts DCC to the first impurity region 112a.

Each of the bit line structures BLS may include a second barrier layer 310, a bit line BL, and/or a dielectric pattern 320 that are sequentially stacked on the bit line contact DCC. The second barrier layer 310 may include a conductive material, such as titanium nitride (TiN), titanium silicon nitride (TiSiN), and/or cobalt silicide (CoSix). The bit line BL may include tungsten (W), aluminum (Al), copper (Co), nickel (Ni), and/or cobalt (Co). The dielectric pattern 320 may be disposed on the bit line BL. The dielectric pattern 320 may include silicon oxide.

A spacer 330 may be provided on the substrate 100. The spacer 330 may cover the sidewall of the bit line contact DCC and a sidewall of the bit line structure BLS. The spacer 330 may include silicon oxide and/or silicon nitride.

A second interlayer dielectric layer 114 may be provided on the substrate 100. For example, the second interlayer dielectric layer 114 may fill an empty space between the bit lines BL facing each other in the second direction Y. The second interlayer dielectric layer 114 may include SiBCN, SiCN, SiOCN, or SiN.

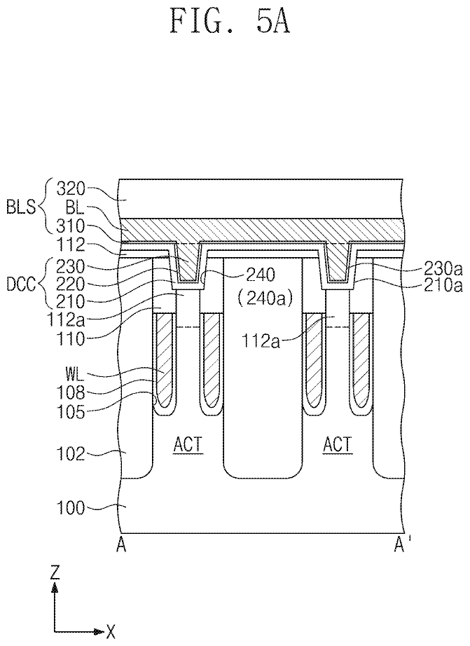

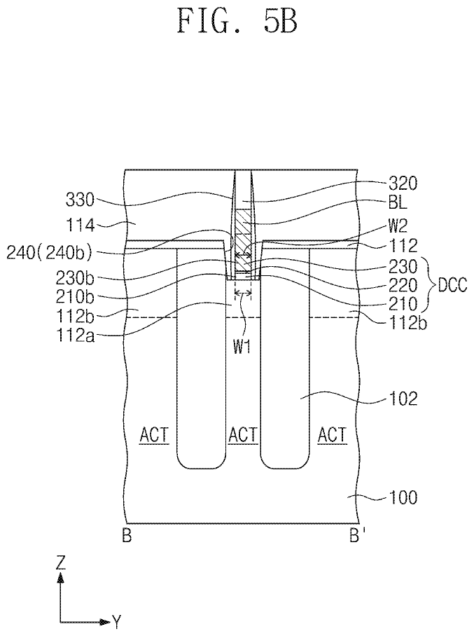

FIGS. 5A and 5B illustrate cross-sectional views respectively taken along lines A-A′ and B-B′ of FIG. 1, showing a semiconductor device according to some example embodiments of inventive concepts. In the example embodiment that follows, components the same as those discussed with reference to FIGS. 2A and 2B are allocated the same reference numerals thereto, and a repetitive explanation thereof will be omitted or abridged for brevity of description.

Referring to FIGS. 1, 5A, and 5B, one bit line BL and its contacted metal layers 230 may be provided as a single body. The metal layers 230 may penetrate the second barrier layer 310, and the top surfaces of the metal layers 230 may contact a bottom surface of the bit line BL. The metal layers 230 and the bit line BL may have a continuous configuration, and invisible boundaries may be provided between the bit line BL and the metal layers 230. For example, the metal layers 230 and the bit line BL may be formed of the same material and/or at the same time, and thus no interfaces may be provided between the metal layers 230 and the bit line BL. In this case, the metal layers 230 and the bit line BL may be collectively connected into a single component. However, inventive concepts are not limited thereto, and visible boundaries may be provided between the bit line BL and the metal layers 230.

The first barrier layer 220 may be connected to the second barrier layer 310. The first barrier layer 220 may have a top surface in contact with a bottom surface of the second barrier layer 310. The first barrier layer 220 and the second barrier layer 310 may have a continuous configuration. The first barrier layer 220 and the second barrier layer 310 may be formed of the same material.

The silicon layer 210 may extend from a lateral surface of the bit line contact DCC into a gap between the first interlayer dielectric layer 112 and a bottom surface of the bit line structure BLS.

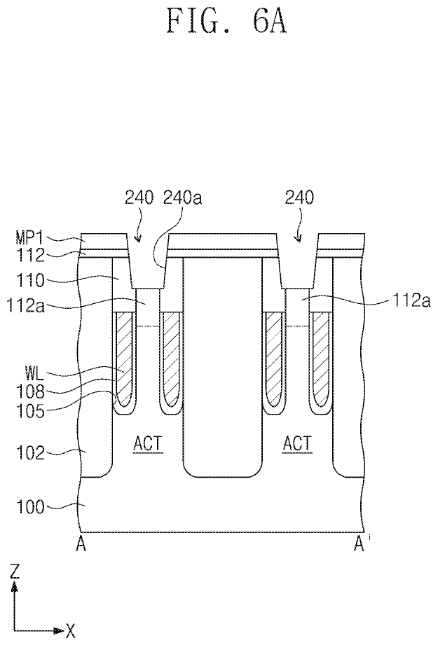

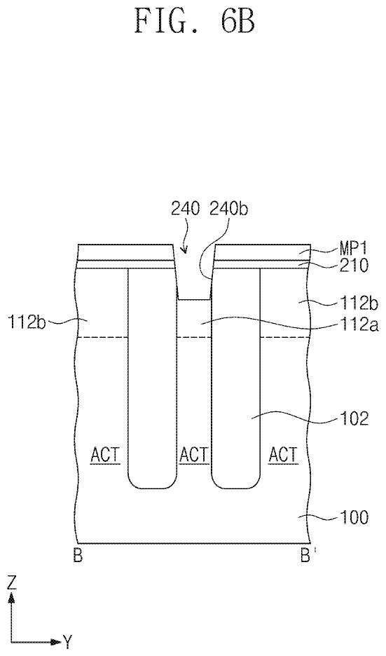

FIGS. 6A, 7A, 8A, 9A, 10A, 11A, and 12A illustrate cross-sectional views taken along line A-A′ of FIG. 1, showing a method of fabricating a semiconductor device according to some example embodiments of inventive concepts. FIGS. 6B, 7B, 8B, 9B, 10B, 11B, and 12B illustrate cross-sectional views taken along line B-B′ of FIG. 1, showing a method of fabricating a semiconductor device according to some example embodiments of inventive concepts.

Referring to FIGS. 1, 6A, and 6B, a device isolation layer 102 including a dielectric material may be formed in a substrate 100. The device isolation layer 102 may be formed by etching the substrate 100 to form a device isolation trench (not shown) in the substrate 100 and filling the device isolation trench with a dielectric material. The device isolation layer 102 may define active regions ACT of the substrate 100. The active regions ACT may have their bar shapes elongated in a third direction S and may be disposed in parallel to each other.

First and second impurity regions 112a and 112b may be formed in the active regions ACT. The first and second impurity regions 112a and 112b may be formed by performing at least one ion implantation process in which impurities are doped into the active regions ACT exposed by at least one ion implantation mask provided on the substrate 100.

Word line trenches 105 (also called recessions above) may be formed in the substrate 100, running across the active regions ACT. The word line trenches 105 may be arranged in a first direction X and may extend in a second direction Y. Two word line trenches 105 may be formed to run across a corresponding one of the active regions ACT. The word line trenches 105 may have their bottom surfaces at a higher level than that of a bottom surface of the device isolation layer 102.

A word line dielectric layer 108 may be formed to conformally cover surfaces of the word line trenches 105. The word line dielectric layer 108 may include a dielectric material, for example, a thermal oxide layer. Alternatively or additionally, the word line dielectric layer 108 may be formed with an ISSG process.

Word lines WL may be formed in the word line trenches 105 on which the word line dielectric layer 108 is formed. For example, a conductive layer may be formed to fill the word line trenches 105. The conductive layer and the word line dielectric layer 108 may undergo a process, such as an etch-back process and/or a chemical mechanical planarization (CMP) process, to form the word lines WL locally remaining in the word line trenches 105. The word lines WL may include a conductive material. For example, the word lines WL may include doped or undoped polysilicon, metal, or metal silicide.

Capping patterns 110 may be formed in upper portions of the word line trenches 105, which upper portions are formed by removing upper portions of the word line dielectric layer 108 and of the word lines WL. The capping patterns 110 may be formed on the word lines WL and may completely fill the word line trenches 105. The capping patterns 110 may include a silicon oxide layer, a silicon nitride layer, or a silicon oxynitride layer.

A first interlayer dielectric layer 112 may be formed on the substrate 100. The first interlayer dielectric layer 112 may include a silicon oxide layer, a silicon nitride layer, a silicon oxynitride layer, or a plurality of dielectric layers including at least two thereof. The first interlayer dielectric layer 112 may be formed with a PECVD process.

A first mask pattern MP1 may be formed on the first interlayer dielectric layer 112, partially exposing the first interlayer dielectric layer 112.

An etching process may be performed to etch portions of the substrate 100 and of the first interlayer dielectric layer 112, which portions are exposed by the first mask pattern MP1. Thus, contact holes 240 may be formed on an upper portion of the substrate 100. For example, the contact holes 240 may be formed by etching portions of the substrate 100 that are positioned on central parts of the active regions ACT. When viewed in plan, i.e. above the surface of the substrate 100 parallel to the X-Y plane, each of the contact holes 240 may expose the first impurity region 112a between a pair of the word lines WL that overlap one active region ACT. When the etching process is performed to form the contact holes 240, the etching process may also partially etch upper portions of the capping patterns 110 and/or an upper portion of the device isolation layer 102, which capping patterns 110 and device isolation layer 102 are adjacent to the first impurity region 112a.

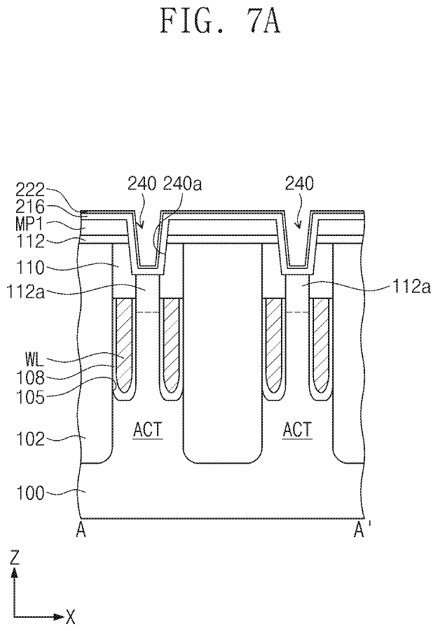

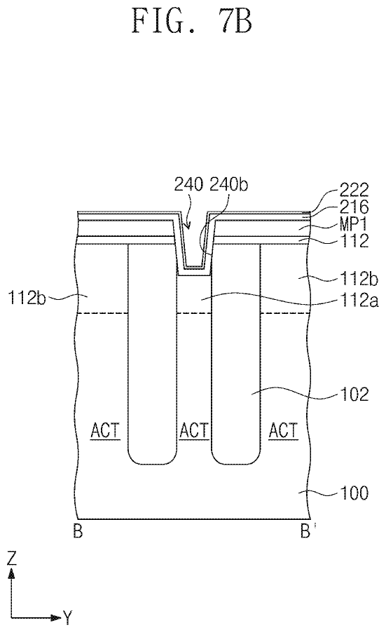

Referring to FIGS. 1, 7A, and 7B, a preliminary silicon layer 216 may be formed on the substrate 100. The preliminary silicon layer 216 may conformally cover a top surface of the first mask pattern MP1 and inner walls 240a and 240b of the contact holes 240. The preliminary silicon layer 216 may include doped or undoped polysilicon. Additionally or alternatively, a doping process may be performed to implant the preliminary silicon layer 216 with impurities.

A first preliminary barrier layer 222 may be formed on the preliminary silicon layer 216. The first preliminary barrier layer 222 may be formed along a top surface of the preliminary silicon layer 216. For example, the first preliminary barrier layer 222 may conformally cover the top surface of the first mask pattern MP1 and the inner walls 240a and 240b of the contact holes 240. The first preliminary barrier layer 222 may include a conductive material, such as titanium nitride (TiN), titanium silicon nitride (TiSiN), and/or cobalt silicide (CoSix).

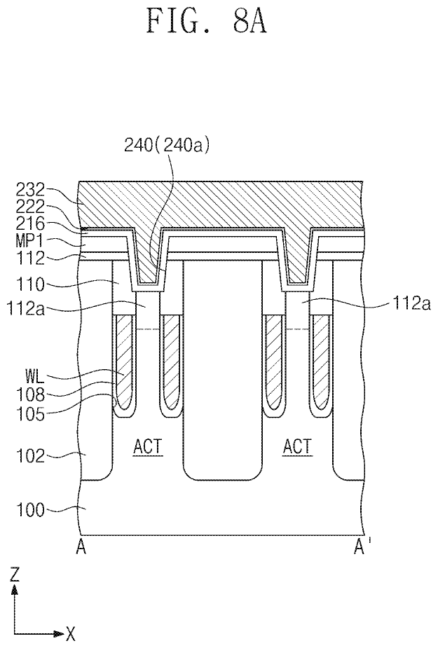

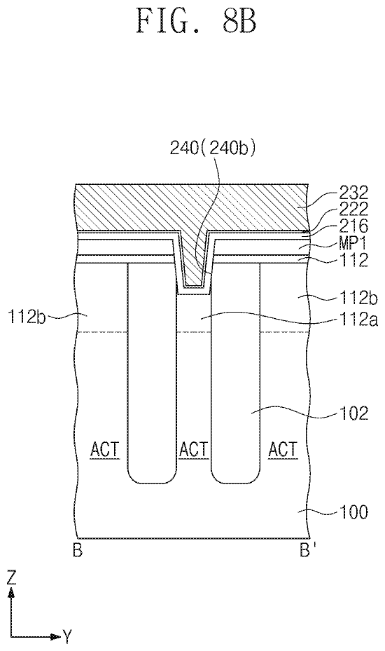

Referring to FIGS. 1, 8A, and 8B, a preliminary metal layer 232 may be formed on the substrate 100. For example, the preliminary metal layer 232 may be formed by depositing a conductive material on the first preliminary barrier layer 222. The preliminary metal layer 232 may be formed to fill the contact holes 240. The preliminary metal layer 232 may include a metallic material, such as tungsten (W) or titanium (Ti), and/or a conductive material, such as titanium nitride (TiN) or titanium silicon nitride (TiSiN).

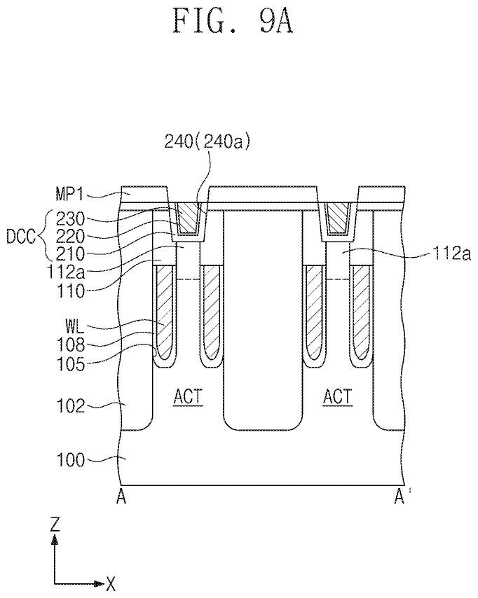

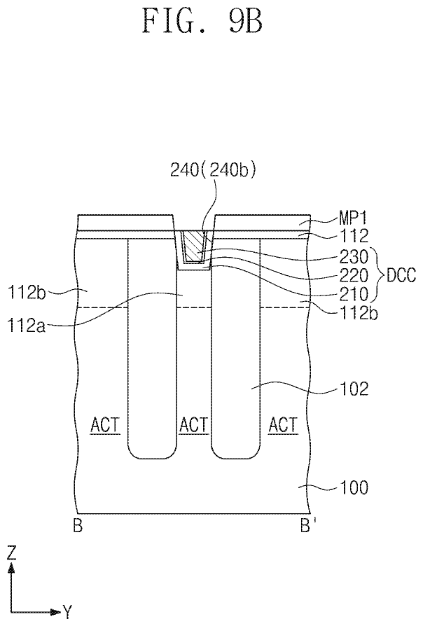

Referring to FIGS. 1, 9A, and 9B, the preliminary silicon layer 216, the first preliminary barrier layer 222, and the preliminary metal layer 232 may be etched to form bit line contacts DCC. Additionally or alternatively, a planarization process (e.g., CMP) may be performed on the preliminary metal layer 232. The planarization process may expose the top surface of the first mask pattern MP1. When the planarization process is performed, the first interlayer dielectric layer 112 may decrease in thickness. An etch-back process may be performed to form the bit line contacts DCC locally remaining in the contact holes 240. The etch-back process may continue until top surfaces of the bit line contacts DCC reach a level the same as that of a top surface of the first interlayer dielectric layer 112.

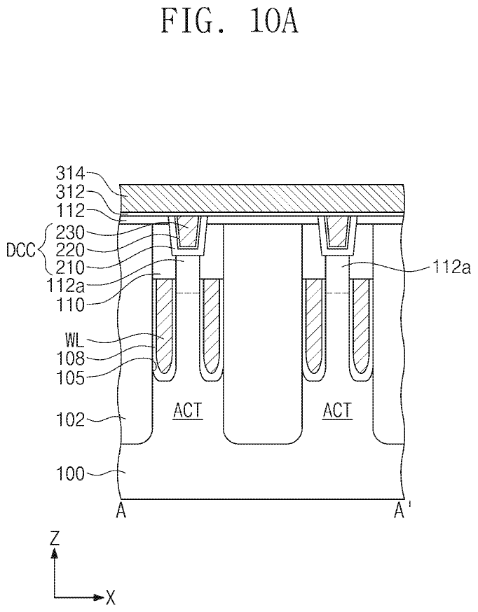

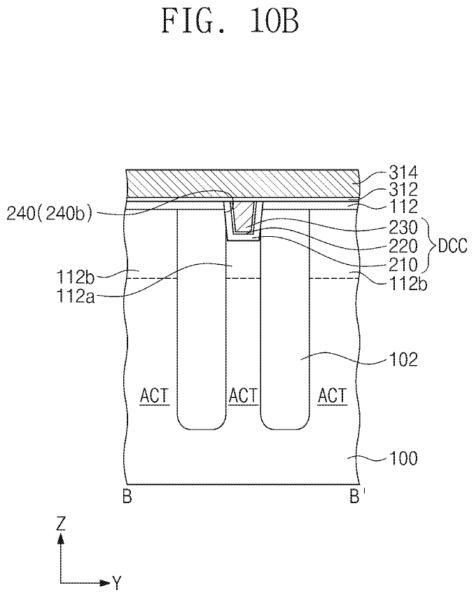

Referring to FIGS. 1, 10A, and 10B, the first mask pattern MP1 may be removed, and then a second preliminary barrier layer 312 may be formed on the substrate 100. The second preliminary barrier layer 312 may be formed by depositing a conductive material, such as titanium nitride (TiN), titanium silicon nitride (TiSiN), and/or cobalt silicide (CoSix), on the top surface of the first interlayer dielectric layer 112 and the top surfaces of the bit line contacts DCC.

A metal layer 314 may be formed on the second preliminary barrier layer 312. The metal layer 314 may be formed by depositing a metallic material, such as tungsten (W), aluminum (Al), copper (Cu), nickel (Ni), and/or cobalt (Co), on the second preliminary barrier layer 312.

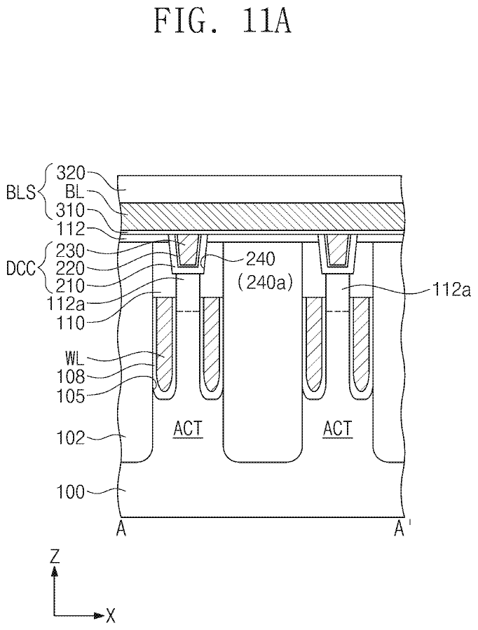

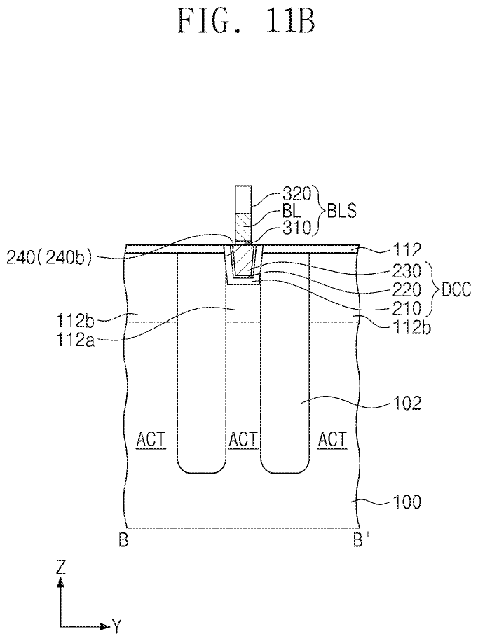

Referring to FIGS. 1, 11A, and 11B, dielectric patterns 320 may be formed on the metal layer 314. The dielectric patterns 320 may extend in the first direction X and may be in parallel to each other. Each of the dielectric patterns 320 may run across the active regions ACT and may cross over the bit line contacts DCC arranged in the first direction X. The dielectric patterns 320 may include, for example, silicon oxide or silicon nitride.

The dielectric patterns 320 may be used as an etching mask to pattern the second preliminary barrier layer 312 and the metal layer 314, with the result that bit line structures BLS may be formed. Each of the bit line structures BLS may include a second barrier layer 310, a bit line BL, and the dielectric pattern 320 that are stacked (e.g. sequentially stacked) on the substrate 100. The second barrier layer 310 and bit line BL are formed by patterning the second preliminary barrier layer 312 and the metal layer 314. A single bit line structure BLS may run across the active regions ACT in the first direction X so as to cross over a plurality of the bit line contacts DCC arranged in the first direction X.

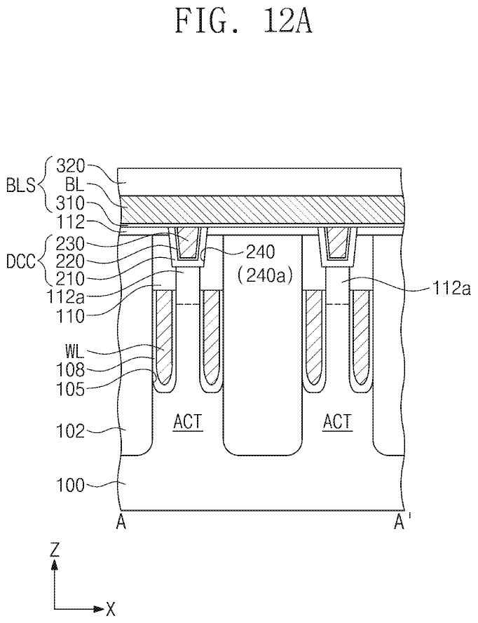

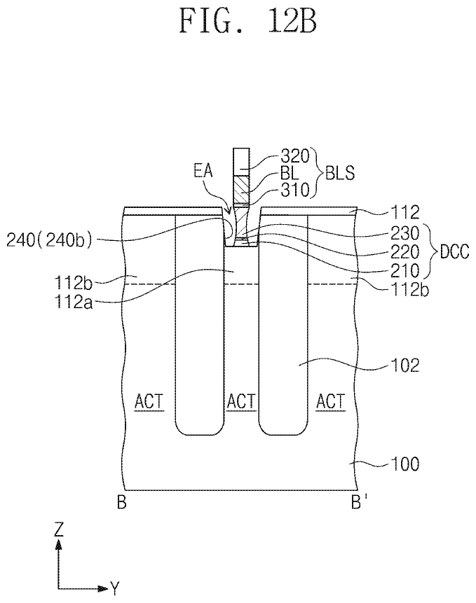

Referring to FIGS. 1, 12A, and 12B, after the bit line structures BLS are formed, an etching process may be performed to partially etch the bit line contacts DCC exposed by the bit line structures BLS. For example, the bit line structures BLS may be used as an etching mask to etch exposed portions of the bit line contacts DCC. The etching process may reduce widths of the bit line contacts DCC. Thus, the bit line contacts DCC may be locally formed in portions of the contact holes 240 below the bit line structures BLS. Because the bit line contacts DCC decrease in width, empty spaces EA may be formed between the contact holes 240 and the bit line contacts DCC. For example, the bit line contact DCC may be formed to have the same width as that of the bit line structure BLS.

According to some example embodiments, during the etching process, the bit line contacts DCC may be over-etched on lateral surfaces thereof. Lower portions of the bit line contacts DCC may be less etched than central portions of the bit line contacts DCC. For example, the bit line contacts DCC may be etched from their upper portions toward their lower portions. As the etching process is performed, the empty spaces EA may be formed from upper portions of the contact holes 240. The central portions of the bit line contacts DCC may be exposed to the etching process for a longer period of time, and thus may be etched more, e.g. over-etched more, than the lower portions of the bit line contacts DCC. For example, after the etching process, the central portions of the bit line contacts DCC may be over-etched and the lower portions of the bit line contacts DCC may not be etched or may only be partially etched. In addition, the bit line structures BLS used as an etching mask may protect the upper portions of the bit line contacts DCC from being over-etched. Therefore, the bit line contact DCC may have a concave lateral surface in the second direction Y. For example, the bit line contact DCC may have a bow shape. When the bit line contacts DCC are over-etched on their lateral surfaces as discussed above, a semiconductor device may be fabricated as shown in FIGS. 4A and 4B. The following will describe an example in which the bit line contact DCC is formed to have the same width as that of the bit line structure BLS.

Referring to FIGS. 1, 2A, and 2B, a spacer 330 may be formed on sidewalls of the bit line contacts DCC and of the bit line structures BLS. For example, a dielectric layer may be formed on the substrate 100 so as to conformally cover the bit line contacts DCC and the bit line structures BLS, and then the dielectric layer may undergo an anisotropic etching process to form the spacer 330.

A second interlayer dielectric layer 114 may be formed on the substrate 100. For example, the second interlayer dielectric layer 114 may fill an empty space between the bit line structures BLS facing each other in the second direction Y and an empty space between the bit line contacts DCC facing each other in the second direction Y. The second interlayer dielectric layer 114 may expose top surfaces of the dielectric patterns 320 of the bit line structures BLS.

Through the processes above, a semiconductor device may be fabricated as shown in FIGS. 2A and 2B.

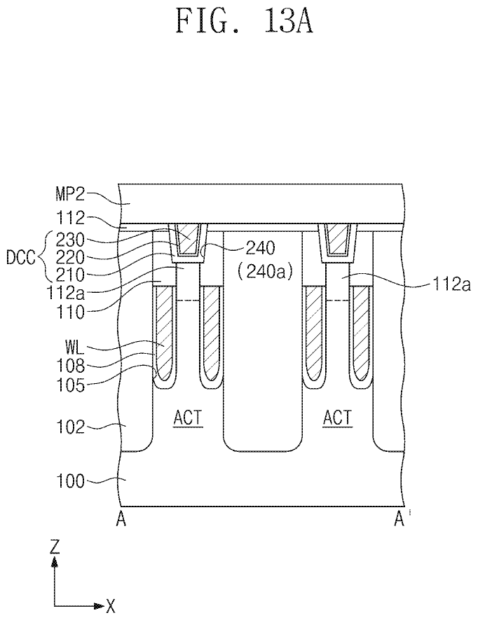

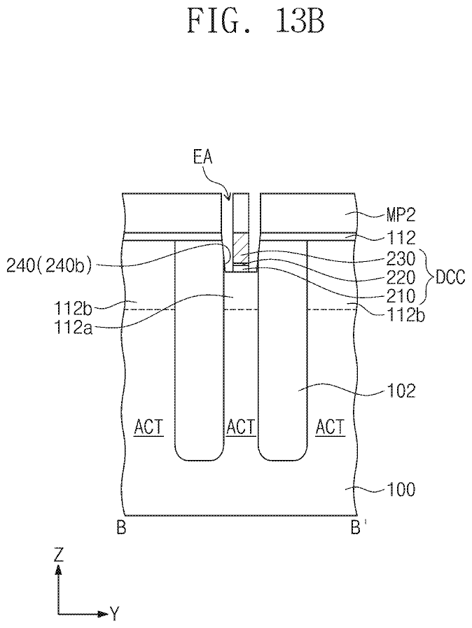

FIGS. 13A, 14A, and 15A illustrate cross-sectional views taken along line A-A′ of FIG. 1, showing a method of fabricating a semiconductor device according to some example embodiments of inventive concepts. FIGS. 13B, 14B, and 15B illustrate cross-sectional views taken along line B-B′ of FIG. 1, showing a method of fabricating a semiconductor device according to some example embodiments of inventive concepts.

Referring to FIGS. 1, 13A, and 13B, the first mask pattern MP1 may be removed from a resultant structure of FIGS. 9A and 9B.

The bit line contacts DCC may be partially etched. For example, a second mask pattern MP2 may be formed on the first interlayer dielectric layer 112 and the bit line contacts DCC. The second mask pattern MP2 may partially expose the top surfaces of the bit line contacts DCC. An etching process may be performed in which the second mask pattern MP2 is used as an etching mask to etch exposed portions of the bit line contacts DCC. The etching process may reduce widths of the bit line contacts DCC. Because the bit line contacts DCC decrease in width, empty spaces EA may be formed between the contact holes 240 and the bit line contacts DCC.

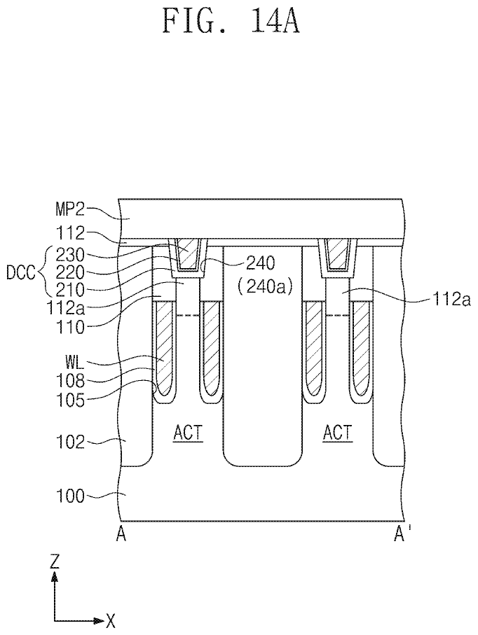

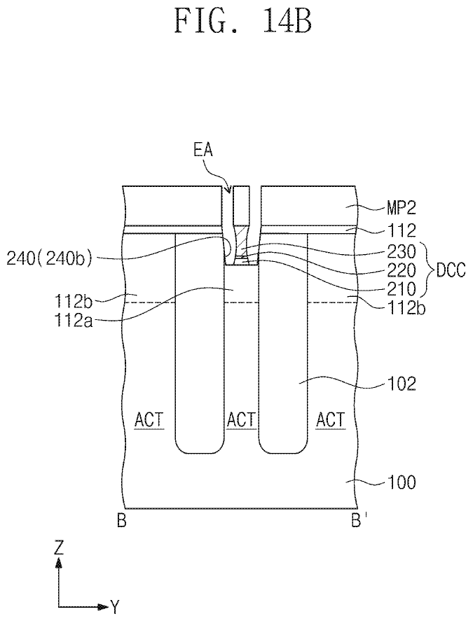

Referring to FIGS. 1, 14A, and 14B, during the etching process, the bit line contacts DCC may be over-etched on lateral surfaces thereof. Lower portions of the bit line contacts DCC may be less etched than central portions of the bit line contacts DCC. For example, the bit line contacts DCC may be etched from their upper portions toward their lower portions. The central portions of the bit line contacts DCC may be exposed to the etching process for a long time, and thus may be over-etched more than the lower portions of the bit line contacts DCC. Therefore, the bit line contact DCC may have a concave lateral surface, e.g. may be bowed, in the second direction Y.

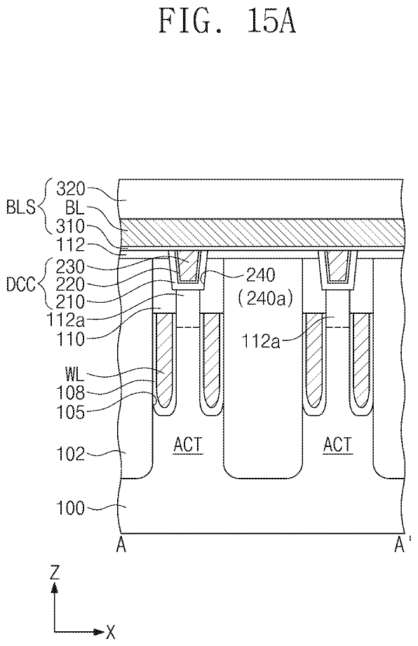

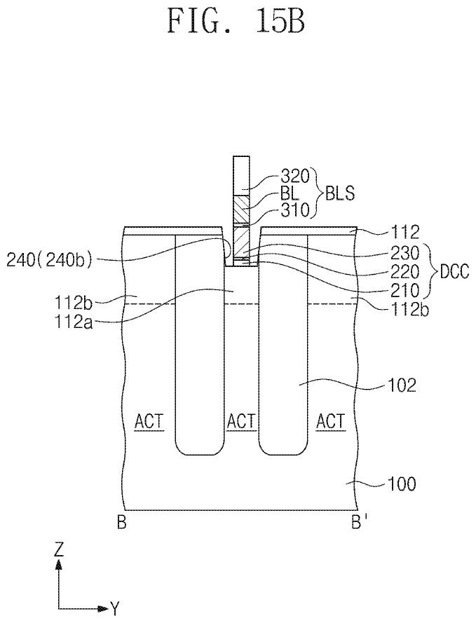

Referring to FIGS. 1, 15A, and 15B, the second mask pattern MP2 may be removed, and then a dielectric material may fill the empty spaces EA of the contact holes 240.

Bit line structures BLS may be formed on the substrate 100. For example, a second preliminary barrier layer, a metal layer, and a dielectric layer may be sequentially deposited on the top surface of the first interlayer dielectric layer 112 and the top surfaces of the bit line contacts DCC, and then the second preliminary barrier layer, the metal layer, and the dielectric layer may be etched to form a second barrier layer 310, a bit line BL, and a dielectric pattern 320.

Referring to FIGS. 1, 2A, and 2B, a spacer 330 may be formed on sidewalls of the bit line contacts DCC and of the bit line structures BLS. A second interlayer dielectric layer 114 may be formed on the substrate 100. For example, the second interlayer dielectric layer 114 may fill an empty space between the bit line structures BLS facing each other in the second direction Y and an empty space between the bit line contacts DCC facing each other in the second direction Y.

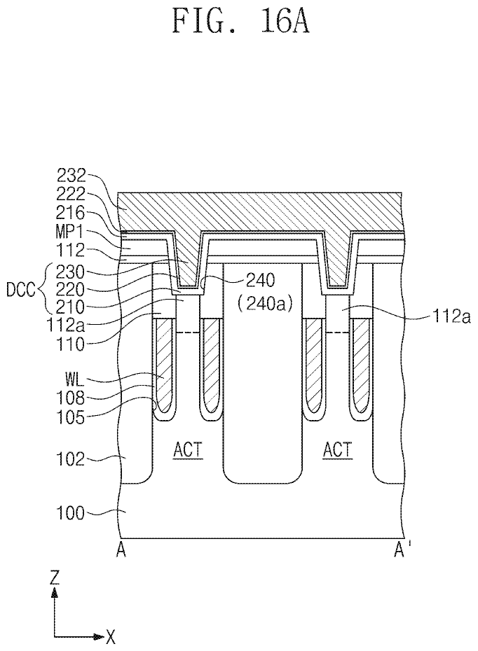

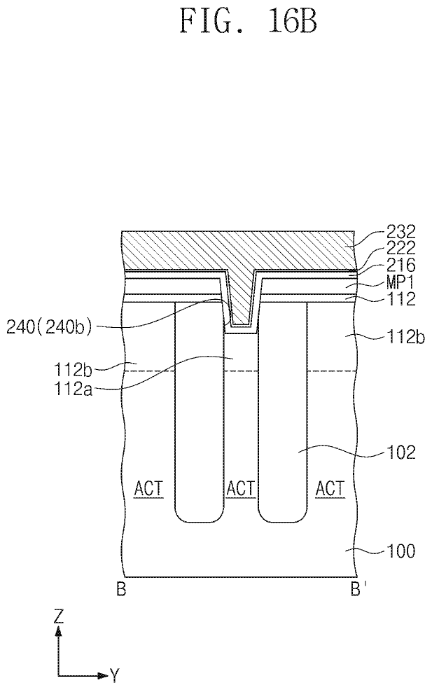

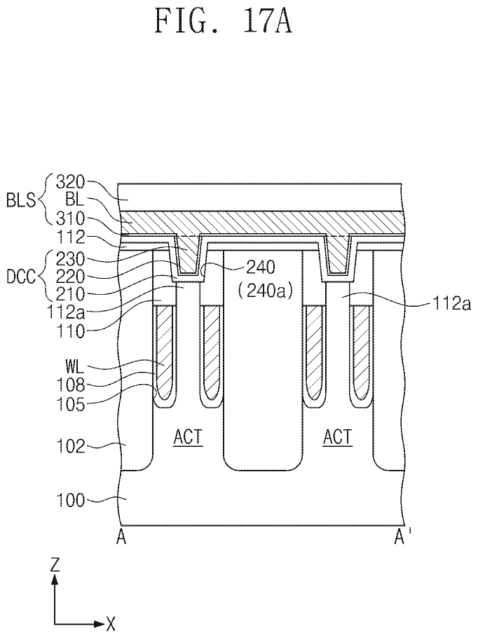

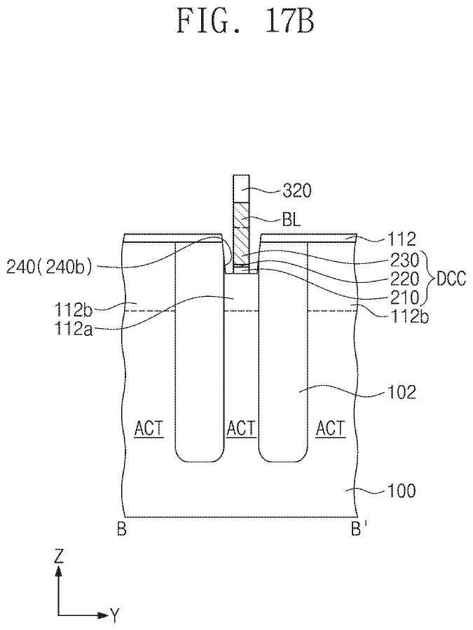

FIGS. 16A and 17A illustrate cross-sectional views taken along line A-A′ of FIG. 1, showing a method of fabricating a semiconductor device according to some example embodiments of inventive concepts. FIGS. 16B and 17B illustrate cross-sectional views taken along line B-B′ of FIG. 1, showing a method of fabricating a semiconductor device according to some example embodiments of inventive concepts.

Referring to FIGS. 1, 16A, and 16B, a preliminary metal layer 232 may be formed on a resultant structure of FIGS. 7A and 7B. For example, the preliminary metal layer 232 may be formed by depositing a conductive material on the first preliminary barrier layer 222. The preliminary metal layer 232 may be formed to fill the contact holes 240 and to cover a top surface of the first preliminary barrier layer 222.

Referring to FIGS. 1, 17A, and 17B, dielectric patterns 320 may be formed on the preliminary metal layer 232. The dielectric patterns 320 may extend in the first direction X and may be in parallel to each other. Each of the dielectric patterns 320 may run across the active regions ACT so as to cross over the bit line contacts DCC arranged in the first direction X.

The dielectric patterns 320 may be used as an etching mask to pattern the preliminary silicon layer 216, the first preliminary barrier layer 222, and the preliminary metal layer 232, with the result that bit line contacts DCC and bit line structures BLS may be formed. The preliminary silicon layer 216 may be patterned to form a silicon layer 210. The first preliminary barrier layer 222 may be patterned to form a first barrier layer 220 and a second barrier layer 310 that are collectively connected into a single body. The preliminary metal layer 232 may be patterned to form a metal layer 230 and a bit line BL that are collectively connected into a single body.

Each of the bit line contacts DCC may include the silicon layer 210, the first barrier layer 220, and the metal layer 230 that are provided in one of the contact holes 240.

Each of bit line structures BLS may include the second barrier layer 310, the bit line BL, and the dielectric pattern 320 that are provided on a plurality of the bit line contacts DCC arranged in the first direction X.

Referring to FIGS. 1, 5A, and 5B, a spacer 330 may be formed on sidewalls of the bit line contacts DCC and of the bit line structures BLS. A second interlayer dielectric layer 114 may be formed on the substrate 100. For example, the second interlayer dielectric layer 114 may fill an empty space between the bit line structures BLS facing each other in the second direction Y and an empty space between the bit line contacts DCC facing each other in the second direction Y.

Through the processes above, a semiconductor device may be fabricated as shown in FIGS. 5A and 5B.

In a semiconductor device according to some example embodiments of inventive concepts, a bit line contact may increase in conductivity because the bit line contact is provided at its central portion with a metal layer formed of metal whose conductivity is high, and the bit line contact may maintain its increased conductivity even when the bit line contact is formed to have a small width.

In addition, a silicon layer may be provided to cover bottom and lateral surfaces of the metal layer, and the silicon layer and the metal layer may have an increased interface at which an ohmic contact is formed. As a result, a reduced resistance may be achieved at the increased interface between the silicon layer and the metal layer, and the bit line contact may decrease in resistance.

Although invention has been described in connection with the some example embodiments of inventive concepts illustrated in the accompanying drawings, it will be understood by one of ordinary skill in the art that variations in form and detail may be made therein without departing from the spirit and essential feature of inventive concepts. The above disclosed embodiments should thus be considered illustrative and not restrictive.

What is claimed is:

1. A semiconductor device, comprising:
a semiconductor substrate;
a first impurity region and a second impurity region spaced apart from each other in the semiconductor substrate;
a bit line on the semiconductor substrate, the bit line extending in a first direction; and
a bit line contact connecting the first impurity region to the bit line,
wherein the bit line contact includes,
a metal layer including a first lateral surface in the first direction and a second lateral surface in a second direction intersecting the first direction, and
a silicon layer covering the first lateral surface of the metal layer and not covering the second lateral surface of the metal layer.

2. The semiconductor device of claim 1, wherein the silicon layer covers the first lateral surface of the metal layer and a bottom surface of the metal layer.

3. The semiconductor device of claim 1, wherein the bit line contact is in a contact hole on a top surface of the semiconductor substrate.

4. The semiconductor device of claim 3, wherein
in the first direction, the bit line contact contacts an inner wall of the contact hole, and
in a second direction, the bit line contact is spaced apart from the inner wall of the contact hole, the second direction intersecting the first direction.

5. The semiconductor device of claim 1, wherein, in a second direction, a width of the metal layer is less than a width of the silicon layer, the second direction intersecting the first direction.

6. The semiconductor device of claim 1, further comprising:
a first barrier layer between the silicon layer and the metal layer.

7. The semiconductor device of claim 1, further comprising:
a second barrier layer on a bottom surface of the bit line.

8. The semiconductor device of claim 7, wherein the second barrier layer extends between the bit line and the bit line contact.

9. The semiconductor device of claim 7, wherein the bit line contact penetrates the second barrier layer, and
the bit line contact contacts the bit line.

10. The semiconductor device of claim 1, wherein the metal layer and the bit line are integrated as a single body.

11. The semiconductor device of claim 1, wherein a width of the bit line contact in the first direction is greater than a width of the bit line contact in a second direction, the second direction intersecting the first direction.

12. The semiconductor device of claim 1, wherein the bit line contact vertically penetrates an interlayer dielectric layer on the substrate and contacts the first impurity region.

13. A semiconductor device, comprising:
a semiconductor substrate;
an interlayer dielectric layer on the semiconductor substrate;
a bit line contact penetrating the interlayer dielectric layer and connecting to the semiconductor substrate; and
a bit line extending in a first direction on the semiconductor substrate and connects to the bit line contact,
wherein the bit line contact includes,
a silicon layer in contact with the semiconductor substrate, and
a metal layer inside the silicon layer,
wherein in a second direction, the silicon layer does not cover a lateral surface of the metal layer, the second direction intersecting the first direction.

14. The semiconductor device of claim 13, wherein the silicon layer comprises:
a bottom segment contacting the semiconductor substrate and extending in the first direction, the bottom segment having a first end and a second end opposite the first end; and
at least two sidewall segments extending toward the bit line from the opposite ends.

15. The semiconductor device of claim 14, wherein the metal layer is on the bottom segment of the silicon layer and between the at least two sidewall segments of the silicon layer.

16. The semiconductor device of claim 14, wherein a top surface of the metal layer is at the same level as top surfaces of the sidewall segments.

17. The semiconductor device of claim 14, further comprising:
a first barrier layer between the metal layer and the bottom segment of the silicon layer and between the metal layer and the sidewall segments of the silicon layer.

18. The semiconductor device of claim 13, wherein
the bit line contact is in a contact hole on a top surface of the semiconductor substrate,
the silicon layer contacts an inner wall of the contact hole, and
the metal layer is spaced apart from the inner wall of the contact hole.

19. The semiconductor device of claim 13, wherein, in the second direction, a lateral surface of the metal layer has a concave shape toward an inside of the metal layer.

20. The semiconductor device of claim 13, wherein the metal layer and the silicon layer contact a bottom surface of the bit line.
